(19) United States
(12) Patent Application Publication
(10) Pub. No.: US 2026/0035785 A1
(43) Pub. Date: Feb. 5, 2026

(54) PROCESS FOR PREPARING COATED ORGANIC PARTICLES

(71) Applicant: BASF SE, Ludwigshafen Am Rhein (DE)

(72) Inventors: Natalie Dehnhardt, Ludwigshafen (DE); Daniel Loeffler, Ludwigshafen (DE); Alexander Georg Hufnagel, Ludwigshafen (DE); Kerstin Schierle-Arndt, Ludwigshafen (DE)

(21) Appl. No.: 19/101,298

(22) PCT Filed: Aug. 4, 2023
(86) PCT No.: PCT/EP2023/071634

§ 371 Date: Feb. 5, 2025

(30) Foreign Application Priority Data
Aug. 10, 2022 (EP) 22189673.1

(51) Int. Cl. C23C 16/44; C23C 16/06; C23C 16/442

(52) U.S. Cl. CPC C23C 16/4417; C23C 16/06; C23C 16/442

(57) ABSTRACT

The present invention is in the field of coated organic particles, in particular comprising small molecules, by using atomic layer deposition. It relates to a process for preparing coated organic particles comprising the steps in the following order: (a) bringing particles containing an organic compound in motion to each other, (b) sequentially contacting the organic particles with a metal- or semimetal-containing compound and a decomposition compound in the gaseous state at a first temperature, and (c) sequentially contacting the organic particles with a metal- or semimetal-containing compound and a decomposition compound in the gaseous state at a second temperature, wherein the second temperature is at least 20° C. above the first temperature. Shell, in particular the density of the inner part of the shell is 5% lower than the density of the outer part of the shell.

### Description

The present invention is in the field of coated organic particles, in particular comprising small molecules, by using atomic layer deposition.

Small molecules, for example pharmaceuticals, agrochemicals, or laundry additives are often formulated in order to achieve effects which the pristine molecules do not have. Examples are protection against certain environments, compatibility in various media or controlled release, i.e. release over an extended period of time. A typical approach to achieve this is to encapsulate the compound such that the contained compound is shielded by the capsule shell and is not or only slowly released, for example by diffusion through the shell. Various techniques are available for encapsulation. Atomic layer deposition is a particularly useful technique, as it allows very precise, uniform and very thin deposition of inorganic or organic-inorganic hybrid materials. This allows for high control of the encapsulation, for example an exact tuning of the release profile, and also high active ingredient loading.

D. Zhang et al. disclose in Nanoscale, volume 9 (2017), pages 11410-11417 the encapsulation of budesonide and lactose. They use a typical atomic layer deposition procedure as it is used in many other applications. However, such a process works for only a very limited number of compounds. Most compounds are destroyed and/or agglomerated in this way.

US 2018/0 221 294 A1 discloses a process for coating particles of pharmaceuticals, such as paracetamol, by ALD using trimethylaluminum. This process involves harsh conditions, hence only very stable compounds like paracetamol can be coated without significant degradation. In addition, the particles tend to agglomerate in this process, so they need to be repeatedly deagglomerated during the process which can hardly be done on an industrially feasible scale.

It was therefore an object of the present invention to provide a coating process which is applicable to a wide range of compounds including sensitive ones. Such a process was aimed for retaining the to be coated compound, leaving it mostly unchanged and at the same time avoid particle agglomeration. The particle shell shall have a very uniform thickness. The process should be robust so it can easily be scaled to industrial scales and allow interference-free production.

These objects were achieved by a process for preparing coated organic particles comprising the steps in the following order:
(a) bringing particles containing an organic compound in motion to each other,
(b) sequentially contacting the organic particles with a metal- or semimetal-containing compound and a decomposition compound in the gaseous state at a first temperature, and
(c) sequentially contacting the organic particles with a metal- or semimetal-containing compound and a decomposition compound in the gaseous state at a second temperature, wherein the second temperature is at least 20° C. above the first temperature.

The present invention further relates to organic particles containing a core and a shell, wherein
the core contains an organic compound and
the shell contains an inner part and an outer part, wherein the inner part and the outer part contain a metal or semimetal and wherein the inner part has a lower index of refraction than the outer part.

The present invention further relates to a composition containing the organic particles according to the present invention.

Preferred embodiments of the present invention can be found in the description and the claims. Combinations of different embodiments fall within the scope of the present invention.

In the process according to the present invention particles containing an organic compound are coated. These particles may also be referred to as organic particles. Organic in the context of the present invention refers to compounds which contain at least one carbon-hydrogen or at least one carbon-carbon bond, preferably they contain at least one carbon-hydrogen and at least one carbon-carbon bond. Often, organic compounds contain more than 80 at.-% of non-metals, preferably more than 90 at.-%, in particular completely or essentially completely. It is even more preferable that the nonmetals are C, H, O, N, S, Se and/or P.

The organic compound can be an agrochemical, such as an insecticide, a fungicide, or a herbicide. Insecticides include insecticides from the class of the carbamates, organophosphates, organochlorine insecticides, phenylpyrazoles, pyrethroids, neonicotinoids, spinosins, avermectins, milbemycins, juvenile hormone analogs, alkyl halides, organotin compounds nereistoxin analogs, benzoylureas, diacylhydrazines, METI acarizides, and insecticides such as chloropicrin, pymetrozin, flonicamid, clofentezin, hexythiazox, etoxazole, diafenthiuron, propargite, tetradifon, chlorofenapyr, DNOC, buprofezine, cyromazine, amitraz, hydramethylnon, acequinocyl, fluacrypyrim, rotenone, or their derivatives.

Fungicides include fungicides from the classes of dinitroanilines, allylamines, anilinopyrimidines, antibiotics, aromatic hydrocarbons, benzenesulfonamides, benzimidazoles, benzisothiazoles, benzophenones, benzothiadiazoles, benzotriazines, benzyl carbamates, carbamates, carboxamides, carboxylic acid diamides, chloronitriles cyanoacetamide oximes, cyanoimidazoles, cyclopropanecarboxamides, dicarboximides, dihydrodioxazines, dinitrophenyl crotonates, dithiocarbamates, dithiolanes, ethylphosphonates, ethylaminothiazolecarboxamides, guanidines, hydroxy-(2-amino)pyrimidines, hydroxyanilides, imidazoles, imidazolinones, inorganic substances, isobenzofuranones, methoxyacrylates, methoxycarbamates, morpholines, N phenylcarbamates, oxazolidinediones, oximinoacetates, oximinoacetamides, peptidylpyrimidine nucleosides, phenylacetamides, phenylamides, phenylpyrroles, phenylureas, phosphonates, phosphorothiolates, phthalamic acids, phthalimides, piperazines, piperidines, propionamides, pyridazinones, pyridines, pyridinylmethylbenzamides, pyrimidinamines, pyrimidines, pyrimidinonehydrazones, pyrroloquinolinones, quinazolinones, quinolines, quinones, sulfamides, sulfamoyltriazoles, thiazolecarboxamides, thiocarbamates, thiophanates, thiophenecarboxamides, toluamides, triphenyltin compounds, triazines, triazoles.

Herbicides include herbicides from the classes of the acetamides, amides, aryloxyphenoxypropionates, benzamides, benzofuran, benzoic acids, benzothiadiazinones, bipyridylium, carbamates, chloroacetamides, chlorocarboxylic acids, cyclohexanediones, dinitroanilines, dinitrophenol, diphenyl ether, glycines, imidazolinones, isoxazoles, isoxazolidinones, nitriles, N-phenylphthalimides, oxadiazoles, oxazolidinediones, oxyacetamides, phenoxycarboxylic acids, phenylcarbamates, phenylpyrazoles, phenylpyrazolines, phenylpyridazines, phosphinic acids, phosphoroamidates, phosphorodithioates, phthalamates, pyrazoles, pyridazinones, pyridines, pyridinecarboxylic acids, pyridinecarboxamides, pyrimidinediones, pyrimidinyl(thio)benzoates, quinolinecarboxylic acids, semicarbazones, sulfonylaminocarbonyltriazolinones, sulfonylureas, tetrazolinones, thiadiazoles, thiocarbamates, triazines, triazinones, triazoles, triazolinones, triazolocarboxamides, triazolopyrimidines, triketones, uracils, ureas. Mixtures of different pesticides are also suitable.

The organic compound can be a pharmaceutical. Pharmaceuticals include antipyretics like ibuprofen, naproxen, ketoprofen, nimesulide, choline salicylate, magnesium salicylate, and sodium salicylate, paracetamol/acetaminophen, nabumetone, phenazone; analgesics like paracetamol/acetaminophen, nonsteroidal anti-inflammatory drugs such as the salicylates, and opioid drugs such as morphine and oxycodone; antimalarial drugs like quinine, chloroquine, amodiaquine, pyrimethamine, proguanil, sulfonamides, mefloquine, atovaquone, primaquine, artemisinin, halofantrine, doxycycline, clindamycin; antibiotics like penicillins, cephalosporins, polymyxins, rifamycins, lipiarmycins, quinolones, sulfonamides, macrolides, lincosamides, tetracyclines, daptomycin, tigecycline, linezolid, fidaxomicin; mood stabilizers like valproate, lamotrigine, carbamazepine, aripiprazole, risperidone, olanzapine, quetiapine, asenapine, paliperidone, ziprasidone, lurasidone; hormone replacements like estrogen and progestogen; oral contraceptives like estrogen, progestin levonorgestrel, ulipristal acetate, mifepristone and misoprostol; stimulants like methylphenidate, amphetamine; tranquilizers like meprobamate, chlorpromazine, reserpine, chlordiazepoxide, diazepam, and alprazolam; or statins like lovastatin, pravastatin, and simvastatin.

The organic compound can be cleaning additives, such as surfactants or chelating agents. Surfactants include non-ionic surfactants such as alkoxylated alcohols, di- and multiblock copolymers of ethylene oxide and propylene oxide and reaction products of sorbitan with ethylene oxide or propylene oxide, alkyl polyglycosides (APG), hydroxyalkyl mixed ethers and amine oxides; anionic surfactants such as alkali metal and ammonium salts of C8-C18-alkyl sulfates, of C8-C18-fatty alcohol polyether sulfates, of sulfuric acid half-esters of ethoxylated C4-C12-alkylphenols (ethoxylation: 1 to 50 mol of ethylene oxide/mol), C12-C18 sulfo fatty acid alkyl esters, for example of C12-C18 sulfo fatty acid methyl esters, furthermore of C12-C18-alkylsulfonic acids and of C10-C18-alkylarylsulfonic acids; amphoteric surfactants such as betains, for example cocamidopropyl betaine (lauramidopropyl betaine). Chelating agents include salts of ethylenediaminetetraacetic acid (EDTA), iminodisuccinic acid (IDS), S,S-ethylenediamine-N,N′-disuccinic acid (EDDS), methylglycinediacetic acid (MGDA), glutamic acid diacetic acid (GLDA), polyaspartic acid, or citrates phosphonates, for example 1-hydroxyethane 1,1-diphosphonic acid (HEDP). Examples for salts include sodium, potassium and ammonium salts, in particular sodium salts, for example methylglycinediacetic acid trisodium salt (MGDA-Na3), glutamic acid diacetic tetrasodium salt (GLDA-Na4) or 1-hydroxyethane 1,1-diphosphonic acid tetrasodium salt (HEDP-Na4).

The organic compound can be a saturated, a mono- or a polyunsaturated fatty acid. Saturated fatty acids include propionic acid, butyric acid, valeric acid, caproic acid, enanthic acid, caprylic acid, pelargonic acid, capric acid, undecylic acid, lauric acid, tridecylic acid, myristic acid, pentadecylic acid, palmitic acid, margaric acid, stearic acid, nonadecylic acid, arachidic acid, heneicosylic acid, behenic acid, tricosylic acid, ILignoceric acid, pentacosylic acid, cerotic acid, heptacosylic acid, montanic acid, nonacosylic acid, melissic acid, henatriacontylic acid, lacceroic acid, psyllic acid, geddic acid, ceroplastic acid and/or hexatriacontylic acid. Mono-unsaturated fatty acids include myristoleic acid, palmitoleic acid, sapienic acid, oleic acid, elaidic acid, vaccenic acid or erucic acid. Polyunsaturated acids (also known as “PUFA”s) may be conjugated fatty acids such as conjugated linoleic acids, linoelaidic acid, α-linolenic acid, arachidonic acid, eicosapentaenoic acid, docosahexaenoic acid or pinolenic acid. Preferred polyunsaturated fatty acids are the so-called omega-3 fatty acids, omega-6 fatty acids and omega-9 fatty acids.

The organic compound can also be a fat containing one or more than one of the fatty acids described above.

The organic compound preferably contains functional groups, in particular hydroxyl groups, aldehyde or ketone groups, ether groups, ester groups, amid groups, amine groups, imine groups, nitrile groups, thiol groups, thioether groups, thioketone groups, sulfoxide groups, sulfone groups, or olefin groups. The organic compound preferably has a molecular weight of less than 2000 g/mol, more preferably less than 1000 g/mol, in particular less than 600 g/mol.

Preferably, the particles have a weight-mean average particle size of 0.5 to 1000 μm, more preferably 1 to 200 μm, even more preferably 1.5 to 100 μm, in particular 2 to 50 μm, for example 2 to 8 μm or 5 to 20 μm. Average particle size is preferably measured by light scattering.

In step (a) of the process according to the present invention, the organic particles are brought in motion to each other. This can be achieved in various ways, for example by using mixers such as plough share mixer, free fall mixer, or blender; dryers such as paddle dryer; acoustic mixers; fluidized bed reactors; spouted bed reactors or rotating drums; spatial reactors such as conveying reactors; vibratory or pulsed-vibratory equipment; or cascades such as a cascade of mixers, dryers or spatial reactors. Combinations of different techniques are also suitable, such as fluidization in combination with vibration. Fluidized bed reactors are preferred, in particular fluidized bed reactors in combination with vibration. Hence, preferably, the organic particles are fluidized.

Bringing the particles in motion to each other typically avoids agglomeration of the particles during the coating process and yields organic particles with more homogeneous coatings. Hence, the organic particles are preferably kept in motion during substantial parts of the coating process, in particular during the whole coating process. The organic particles are preferably kept in motion during step (b), more preferably, the organic particles are kept in motion during step (b) and step (c). Step (a) may be operated such that it constitutes a drying step. This can be done by purging the organic particles with dry air or an inert gas such as nitrogen or argon, for example for 10 min to 2 h, at room temperature or elevated temperature, for example 30 to 80° C.

Preferably, the organic particles are brought in contact with a pretreatment compound in the gaseous state before step (b), i.e. before the organic particles are brought in contact with the metal- or semimetal-containing compound. The pretreatment compound is preferably water, an alcohol or a carboxylic acid. Alcohols include mono alcohols like methanol, ethanol, n-propanol, isopropanol, n-butanol, sec-butanol, iso-butanol, tert-butanol; and diols like ethylene-diol, propylene-1,2-diol, butane-1,2-diol, butane-1,4-diol, hexane-1,2-diol, hexane-1,4-diol. Carboxylic acids include monocarboxylic acids like formic acid, acetic acid, propionic acid, butyric acid, lactic acid, pyruvic acid, glycine, alanine; and dicarboxylic acids like oxalic acid, malonic acid, glutaric acid, adipic acid, maleic acid, fumaric acid, citric acid, tartronic acid, mesoxalic acid, tartaric acid, malic acid. Preferably, the pretreatment compound has molecular weight of 500 g/mol or less, in particular 200 g/mol or less. Preferably, the pretreatment compound has a vapor pressure of at least 1 mbar at 80° C. Preferably, the organic particles are brought in contact with a pretreatment compound in the gaseous state while the organic particles are kept in motion.

Preferably, the organic particles are brought in contact with the pretreatment compound for 1 s to 30 min, in particular 1 min to 10 min. Preferably, the organic particles are brought in contact with the pretreatment compound at a temperature of 0° C. to 150° C., more preferably 20° C. to 120° C., in particular 25° C. to 80° C. Preferably, the organic particles are brought in contact with the pretreatment compound at a partial pressure of the pretreatment compound of 1 mbar to 1 bar, more preferably 2 to 100 mbar, in particular 5 to 100 mbar. Preferably, the organic particles are brought in contact with a mixture of the pretreatment compound in the gaseous state and an inert gas, for example nitrogen or argon. The mixture of the pretreatment compound in the gaseous state and an inert gas may have a pressure around ambient pressure, such as 0.8 to 1.2 bar. The pretreatment compound can be brought into the gaseous state by techniques described for the metal-or semimetal-containing compound described below. Preferably, any excess pretreatment compound is removed from the gaseous state after the organic particles have been brought in contact with the pretreatment compound and before the organic particles are brought in contact with the metal- or semimetal-containing compound. Such removal can be effected by evacuation or purging, for example with an inert gas such as nitrogen or argon. Evacuation or purging can take 10 s to 1 h, preferably 1 to 45 min, in particular 5 to 30 min.

According to the present invention, in step (b) the organic particles are sequentially contacted with a metal-or semimetal-containing compound and a decomposition compound in the gaseous state at a first temperature. Sequentially may mean that the organic particles are firstly brought in contact with a metal-or semimetal-containing compound and subsequently with a decomposition compound. Hence, a sequence is performed which contains contacting the organic particles with a metal- or semimetal-containing compound and contacting the organic particles with a decomposition compound. This sequence can be performed 1 to 500 times, preferably 2 to 100 times, for example 3 to 20 times or 10 to 50 times. Preferably, the organic particles are contacted with the metal-or semimetal-containing compound for 10 s to 1 h, preferably 1 to 45 min, in particular 5 to 30 min.

Preferably, residual metal- or semimetal-containing compound in the gaseous state is removed before the organic particles are brought in contact to the decomposition compound. Preferably, residual decomposition compound in the gaseous state is removed before the organic particles are brought in contact to the metal- or semimetal-containing compound. Removal can be achieved by evacuation or by purging with an inert gas, for example nitrogen or argon. Hence, the sequence may contain contacting the organic particles with a metal- or semimetal-containing compound, removing residual metal-or semimetal-containing compound from the gas phase, contacting the organic particles with a decomposition compound and removing residual decomposition compound from the gas phase. Evacuation or purging can take 10 s to 1 h, preferably 1 to 45 min, in particular 5 to 30 min.

Preferably, the metal-or semimetal-containing compound is capable of reacting with the organic compound on the surface of the particles, i.e. is able to form permanent bonds with the particles. The metal- or semimetal-containing compound contains at least one metal or semimetal atom. Metals include Li, Be, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Cs, Ba, La, Ce, Pr, Nd, Pm, Sm, Eu, Gd, Tb, Dy, Ho, Er, Tm, Yb, Lu, Hf, Ta, W, Re, Os Ir, Pt, Au, Hg, Tl, Bi. Semimetals include B, Si, Ge, As, Sb, Se, Te. Preferably, the metal-or semimetal-containing compound contains Ti, Al, Si, Fe, Mg, Zn, Sn, Zr, or Hf. It is possible that more than one metal- or semimetal-containing compound is used, either simultaneously or consecutively. If more than one metal- or semimetal-containing compound is used it is possible that all metal-or semimetal-containing compounds contain the same metal or semimetals or different ones, preferably they contain different metals or semimetals.

A wide variety of metal- or semimetal-containing compound, which can be brought into the gaseous state, is suitable. These compounds include metal or semimetal alkyls such as dimethyl zinc, or trimethyl aluminum; metal alkoxylates such as tetramethoxy silicon, tetra-isopropoxy zirconium, tetra-iso-propoxy titanium or dimethyl-isopropoxy aluminum; metal or semimetal cyclopentadienyl complexes like pentamethylcyclopentadienyl-trimethoxy titanium or di(ethylcycopentadienyl) manganese; metal or semimetal carbenes such as tris(neopentyl)neopentylidene tantalum or bisimidazolidinyliden ruthenium chloride; metal or semimetal halides such as aluminum trichloride, silicon tetrachloride, tantalum pentachloride, titanium tetrachloride, molybdenum pentachloride, germanium tetrachloride, gallium trichloride, arsenic trichloride or tungsten hexachloride; carbon monoxide complexes like hexacarbonyl chromium or tetracarbonyl nickel; amine complexes such as bis(tert-butylimino)-bis(dimethylamido) molybdenum, bis(tert-butylimino)bis(dimethylamido) tungsten or tetrakis(dimethylamido) titanium, di(isopropylamino)silane; diketonate complexes such as tris(acetylacetonato) aluminum or bis (2,2,6,6-tetramethyl-3,5-heptanedionato) manganese. Metal or semimetal alkyls are preferred, in particular trimethylaluminum. It is preferred that the molecular weight of the metal- or semimetal-containing compound is up to 1000 g/mol, more preferred up to 800 g/mol, in particular up to 600 g/mol, such as up to 500 g/mol. Preferably, the metal-or semimetal-containing compound has a vapor pressure of at least 1 mbar at 80° C.

Preferably, the decomposition compound is capable of reacting with the metal- or semimetal-containing compound and thereby forming functional groups which can react with further metal- or semimetal-containing compound. Various decomposition compounds are suitable including a plasma like an oxygen plasma, hydrogen plasma, ammonia plasma, nitrous oxide or nitrogen plasma; oxidants like oxygen, oxygen radicals, ozone, nitrous oxide (N₂O), nitric oxide (NO), nitrogendioxde (NO₂) or hydrogenperoxide; ammonia or ammonia derivatives for example tertbutylamine, iso-propylamine, dimethylamine, methylethylamine, or diethylamine; hydrazine or hydrazine derivatives like N, N-dimethylhydrazine; solvents like water, alkanes, or tetrachlorocarbon; phosphor compounds like phosphor chloride, phosphane, trimethylphosphor, hexamethylphosphor triamide (HMTP) or trimethylphosphonate; alcohols including monoalcohols like isopropanol or n-butanol and diols like ethylenediol, propylenediol, butane-1,4-diol, hexane-1,6-diol; thiols, in particular thiols further containing a hydroxyl group like 4-mercaptophenol or 4-mercapotbenzylic alcohol; or boron compound like borane. The choice depends on the chemical structure of the desired inorganic compound. For oxides, it is preferable to use oxidants, plasma or water, in particular oxygen, water, oxygen plasma or ozone. For nitrides, it is preferably to use ammonia, hydrazine, hydrazine derivatives, nitrogen plasma or ammonia plasma. For borides, it is preferable to use boron compounds. For carbides, it is preferable to use alkanes or tetrachlorocarbon. For carbide nitrides, it is preferable to use mixtures including alkanes, tetrachlorocarbon, ammonia and/or hydrazine. Preferably, the decomposition compound has a vapor pressure of at least 1 mbar at 80° C.

The metal- or semimetal-containing compound and the decomposition compound are in the gaseous state when brought in contact with the organic particles. They can be brought into the gaseous state for example by heating them to elevated temperatures. In any case a temperature below the decomposition temperature of the metal- or semimetal-containing compound or the decomposition compound has to be chosen. The decomposition temperature is the temperature at which the pristine metal-or semimetal-containing compound or the decomposition compound begins changing its chemical structure and composition. Preferably, the heating temperature ranges from 0° C. to 300° C., more preferably from 10° C. to 200° C., even more preferably from 15° C. to 150° C., in particular from 20° C. to 100° C.

Another way of bringing the metal- or semimetal-containing compound or the decomposition compound into the gaseous state is direct liquid injection (DLI) as described for example in US 2009/0 226 612 A1. In this method the metal- or semimetal-containing compound or the decomposition compound is typically dissolved in a solvent and sprayed in a carrier gas or vacuum. If the vapor pressure and the temperature of the metal- or semimetal-containing compound or the decomposition compound are sufficiently high and the pressure is sufficiently low the metal-or semimetal-containing compound or the decomposition compound is brought into the gaseous state. Various solvents can be used provided that the metal- or semimetal-containing compound or the decomposition compound shows sufficient solubility in that solvent such as at least 1 g/l, preferably at least 10 g/l, more preferably at least 100 g/l. Examples for these solvents are coordinating solvents such as tetrahydrofuran, dioxane, diethoxyethane, pyridine or non-coordinating solvents such as hexane, heptane, benzene, toluene, or xylene. Solvent mixtures are also suitable.

Alternatively, the metal- or semimetal-containing compound or the decomposition compound can be brought into the gaseous state by direct liquid evaporation (DLE) as described for example by J. Yang et al. (Journal of Materials Chemistry C, volume 3 (2015), pages 12098-12106). In this method, the metal- or semimetal-containing compound is mixed with a solvent, for example a hydrocarbon such as tetradecane, and heated below the boiling point of the solvent. By evaporation of the solvent, the metal- or semimetal-containing compound or the decomposition compound is brought into the gaseous state. This method has the advantage that no particulate contaminants are formed.

It is preferred to bring the metal- or semimetal-containing compound or the decomposition compound into the gaseous state at decreased pressure. In this way, the process can usually be performed at lower heating temperatures leading to decreased decomposition of the metal- or semimetal-containing compound. It is also possible to use increased pressure to push the metal- or semimetal-containing compound or the decomposition compound in the gaseous state towards the solid substrate. Preferably, a pressure around ambient pressure, such as 0.8 to 1.2 bar, is used. Often, an inert gas, such as nitrogen or argon, is used as carrier gas for this purpose. Preferably, the partial pressure of the metal- or semimetal-containing compound or the decomposition compound is 100 to 10⁻³ mbar, more preferably 10 mbar to 0.01 mbar, in particular 5 to 0.05 mbar, such as 1 to 0.1 mbar.

The metal- or semimetal-containing compound and the decomposition compound used in the process according to the present invention are used at high purity to achieve the best results. High purity means that the substance used contains at least 90 wt.-% metal- or semimetal-containing compound and the decomposition compound, preferably at least 95 wt.-%, more preferably at least 98 wt.-%, in particular at least 99 wt.-%. The purity can be determined by elemental analysis according to DIN 51721 (Prüfung fester Brennstoffe—Bestimmung des Gehaltes an Kohlenstoff und Wasserstoff—Verfahren nach Radmacher-Hoverath, August 2001).

Contacting the organic particles with the metal- or semimetal-containing compound and the decomposition compound in step (b) is performed at a first temperature. The first temperature refers to the temperature of the organic particles while they are brought in contact with the metal- or semimetal-containing compound and the decomposition compound in step (b). The temperature or the organic particles is typically controlled by adjusting the temperature of the gas and the apparatus surrounding the organic particles. The first temperature can be 20° C. to 100° C., preferably 40° C. to 90° C., in particular 50° C. to 80° C.

The process according to the present invention further comprises (c) sequentially contacting the organic particles with a metal- or semimetal-containing compound and a decomposition compound. As for step (b) a sequence can be performed which contains contacting the organic particles with a metal-or semimetal-containing compound and contacting the organic particles with a decomposition compound. This sequence can be performed 1 to 500 times, preferably 2 to 100 times, for example 3 to 20 times or 10 to 50 times. The sequence of step (c) can be performed fewer times than the sequence of step (b) or equal times or more often. Preferably, the sequence of step (c) is performed more times than the sequence of step (b), for example the sequence of step (c) is performed at least 1.5 times the sequence of step (b) or the sequence of step (c) is performed at least two times the sequence of step (b).

Preferably, residual metal- or semimetal-containing compound in the gaseous state is removed before the organic particles are brought in contact to the decomposition compound. Preferably, residual decomposition compound in the gaseous state is removed before the organic particles are brought in contact to the metal- or semimetal-containing compound. Removal can be achieved by evacuation or by purging with an inert gas, for example nitrogen or argon. Hence, the sequence may contain contacting the organic particles with a metal- or semimetal-containing compound, removing residual metal-or semimetal-containing compound from the gas phase, contacting the organic particles with a decomposition compound and removing residual decomposition compound from the gas phase. Evacuation or purging can take 10 s to 1 h, preferably 1 to 45 min, in particular 5 to 30 min.

Contacting the organic particles with the metal- or semimetal-containing compound and the decomposition compound in step (c) is performed at a second temperature. The second temperature refers to the temperature of the organic particles while they are brought in contact to the metal- or semimetal-containing compound and the decomposition compound in step (c). The temperature or the organic particles is typically controlled by adjusting the temperature of the gas and the apparatus surrounding the organic particles. The second temperature can be 40° C. to 200° C., preferably 60° C. to 150° C., in particular 80° C. to 120° C.

According to the present invention, the second temperature is at least 20° C. above the first temperature, preferably at least 25° C., in particular at least 30° C., for example at least 35° C. or at least 40° C. It has been surprisingly found that such temperature difference makes the process suitable even for organic particles containing a sensitive compound and leads to a very low degree of agglomeration.

It is possible to use the same metal- or semimetal-containing compound in step (c) as in step (b) or a different one, preferably a different one. The description of the metal- or semimetal-containing compound and preferred embodiments above apply also to step (c). It is possible to use the same decomposition compound in step (c) as in step (b) or a different one, preferably a different one. The description of the decomposition compound and preferred embodiments above apply also to step (c). Also, the methods of bringing the metal- or semimetal-containing compound and the decomposition compound in the gaseous state described above apply to step (c).

The method of the present invention may comprise the steps in the following order:
(a) bringing particles containing an organic compound in motion to each other,
(b) sequentially contacting the organic particles with a first metal- or semimetal-containing compound and a first decomposition compound in the gaseous state at a first temperature, and
(c) sequentially contacting the fluidized organic particles with a second metal- or semimetal-containing compound and a second decomposition compound in the gaseous state at a second temperature,
wherein the second temperature is at least 20° C. above the first temperature.

Preferably, the reaction enthalpy of the reaction of the first metal- or semimetal-containing compound with the first decomposition compound is lower than the reaction enthalpy of the reaction of the second metal- or semimetal-containing compound with the second decomposition compound, preferably the reaction enthalpy of the reaction of the first metal- or semimetal-containing compound with the first decomposition compound is 20% lower than the reaction enthalpy of the reaction of the second metal- or semimetal-containing compound with the second decomposition compound, in particular the reaction enthalpy of the reaction of the first metal- or semimetal-containing compound with the first decomposition compound is 30% lower than the reaction enthalpy of the reaction of the second metal- or semimetal-containing compound with the second decomposition compound. The reaction enthalpy of the reaction of the first metal- or semimetal-containing compound with the first decomposition compound at 25° C. may be less than 800 KJ/mol, in particular less than 600 KJ/mol. The reaction enthalpy of the reaction of the second metal- or semimetal-containing compound with the second decomposition compound at 25° C. may be more than 800 KJ/mol, in particular more than 1000 KJ/mol.

The reaction enthalpy may be obtained by calculating the difference between the standard formation enthalpies of the reagents and the products of the reaction between the metal- or semimetal-containing compound with the decomposition compound. Standard formation enthalpies can be found in various databases, for example from the NIST Chemistry WebBook (https://webbook.nist.gov/chemistry) or the Detherm database (https://i-systems.dechema.de/detherm/mixture.php).

The first metal- or semimetal-containing compound may be less reactive than the second metal- or semimetal-containing compound while the first decomposition compound and the second decomposition compound are the same. For example, the first metal-or semimetal-containing compound may be one of diethyl zinc, silicon tetrachloride, tetrakis (dimethylamido) titanium (IV) or titanium tetrachloride. The second metal- or semimetal-containing compound may be one of trimethylaluminum or dimethylaluminium isopropoxide.

The first decomposition compound may be less reactive with the first metal- or semimetal-containing compound than the second decomposition compound with the second metal- or semimetal-containing compound while the first metal-or semimetal-containing compound and the second metal- or semimetal-containing compound are the same. For example, the first decomposition compound may be isopropanol and the second decomposition compound may be water.

The first decomposition compound may be less reactive with the first metal- or semimetal-containing compound than the second decomposition compound with the second metal- or semimetal-containing compound while both the first metal- or semimetal-containing compound and the second metal- or semimetal-containing compound are different to each other, and the first decomposition compound is different to the second decomposition compound. For example, the first metal- or semimetal-containing compound may be diethyl zinc, the first decomposition compound may be water, the second metal- or semimetal-containing compound may be trimethyl aluminum, and the second decomposition compound may be ozone.

The present invention also relates to organic particles which can be obtained be the process according to the present invention. Unless explicitly stated to the contrary below, any description related to the process including preferred embodiments applies to the organic particles. The organic particles contain a core and a shell surrounding the core.

The core contains an organic compound as described above for the process. Preferably, the core has a weight-mean average particle size of 0.5 to 1000 μm, more preferably 1 to 200 μm, even more preferably 2 to 100 μm, in particular 3 to 50 μm, for example 5 to 20 μm. Average particle size is preferably measured by light scattering.

The shell contains an inner part and an outer part, wherein the inner part and the outer part contain a metal or semimetal. Metals include Li, Be, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Cs, Ba, La, Ce, Pr, Nd, Pm, Sm, Eu, Gd, Tb, Dy, Ho, Er, Tm, Yb, Lu, Hf, Ta, W, Re, Os Ir, Pt, Au, Hg, Tl, Bi. Semimetals include B, Si, Ge, As, Sb, Se, Te. Preferably, the metal-or semimetal-containing compound contains Ti, Al, Fe, Mg, Zn, Sn, Zr, or Hf. The shell can contain an inorganic compound, for example a metal or semimetal oxide, nitride, boride, carbide, or carbide nitride of a metal or semimetal. The inorganic compound can contain one metal or semimetal or more than one metal or semimetal. Preferably, the shell contains at least 90 wt-% inorganic compound, even more preferably at least 95 wt.-%, in particular at least 98 wt.-%.

The inner part of the shell has a lower index of refraction than the outer part of the shell. Without being wished to be bound by any theory, it is believed that the lower temperature at which the inner part of the shell is made causes the lower index of refraction, potentially due to incomplete chemical conversion and thus lower crystallinity and more crystal defects. The dependence of the refractive index on the temperature of film deposition has been shown by M. D. Groner et al. in Chemistry of Materials, volume 16 (2004), pages 639-645. The index of refraction can be measured by phase-contrast imaging, for example by Zernike phase-contrast microscopy, differential interference contrast microscopy (DIC), or interferometry. Preferably, the refractive index of the inner part of the shell is 0.05 higher than the refractive index of the outer part of the shell, in particular the refractive index of the inner part of the shell is 0.1 higher than the refractive index of the outer part of the shell.

The inner part of the shell may have a lower density than the outer part of the shell. Preferably, the density of the inner part of the shell is 2% lower than the density of the outer part of the s propagation materials, such as seeds (e.g. GF). These and further composition types are defined in the “Catalogue of pesticide formulation types and international coding system”, Technical Monograph No. 2, 6^{th} Ed. May 2008, CropLife International.

The compositions are prepared in a known manner, such as described by Mollet and Grubemann, Formulation technology, Wiley VCH, Weinheim, 2001; or Knowles, New developments in crop protection product formulation, Agrow Reports DS243, T&F Informa, London, 2005.

Preferably, the composition contains one or more auxiliaries selected from solvents, liquid carriers, solid carriers or fillers, surfactants, dispersants, emulsifiers, wetters, adjuvants, solubilizers, penetration enhancers, protective colloids, adhesion agents, thickeners, humectants, repellents, attractants, feeding stimulants, compatibilizers, bactericides, anti-freezing agents, anti-foaming agents, colorants, tackifiers and binders.

Suitable solvents and liquid carriers are water and organic solvents, such as mineral oil fractions of medium to high boiling point, e.g. kerosene, diesel oil; oils of vegetable or animal origin; aliphatic, cyclic and aromatic hydrocarbons, e. g. toluene, paraffin, tetrahydronaphthalene, alkylated naphthalenes; alcohols, e.g. ethanol, propanol, butanol, benzyl alcohol, cyclohexanol; glycols; DMSO; ketones, e.g. cyclohexanone; esters, e.g. lactates, carbonates, fatty acid esters, gamma-butyrolactone; fatty acids; phosphonates; amines; amides, e.g. N-methylpyrrolidone, fatty acid dimethylamides; and mixtures thereof.

Suitable solid carriers or fillers are mineral earths, e.g. silicates, silica gels, talc, kaolins, limestone, lime, chalk, clays, dolomite, diatomaceous earth, bentonite, calcium sulfate, magnesium sulfate, magnesium oxide; polysaccharide powders, e.g. cellulose, starch; fertilizers, e.g. ammonium sulfate, ammonium phosphate, ammonium nitrate, ureas; products of vegetable origin, e.g. cereal meal, tree bark meal, wood meal, nutshell meal, and mixtures thereof.

Suitable surfactants are surface-active compounds, such as anionic, cationic, non-ionic and amphoteric surfactants, block polymers, polyelectrolytes, and mixtures thereof. Such surfactants can be used as emulsifier, dispersant, solubilizer, wetter, penetration enhancer, protective colloid, or adjuvant. Examples of surfactants are listed in Mccutcheon's, Vol. 1: Emulsifiers & Detergents, Mccutcheon's Directories, Glen Rock, USA, 2008 (International Ed. or North American Ed.).

Suitable anionic surfactants are alkali, alkaline earth or ammonium salts of sulfonates, sulphates, phosphates, carboxylates, and mixtures thereof. Examples of sulfonates are alkylarylsulfonates, diphenyl sulfonates, alpha-olefin sulfonates, lignin sulfonates, sulfonates of fatty acids and oils, sulfonates of ethoxylated alkyl phenols, sulfonates of alkoxylated aryl phenols, sulfonates of condensed naphthalenes, sulfonates of dodecyl-and tridecylbenzenes, sulfonates of naphthalenes and alkylnaphthalenes, sulfosuccinates or sulfosuccinamates. Examples of sulphates are sulphates of fatty acids and oils, of ethoxylated alkylphenols, of alcohols, of ethoxylated alcohols, or of fatty acid esters. Examples of phosphates are phosphate esters. Examples of carboxylates are alkyl carboxylates, and carboxylated alcohol or alkyl phenol ethoxylate. Suitable non-ionic surfactants are alkoxylates, N-substituted fatty acid amides, amine oxides, esters, sugar-based surfactants, polymeric surfactants, and mixtures thereof. Examples of alkoxylates are compounds such as alcohols, alkyl phenols, amines, amides, aryl phenols, fatty acids or fatty acid esters which have been alkoxylated with 1 to 50 equivalents. Ethylene oxide and/or propylene oxide may be employed for the alkoxylation, preferably ethylene oxide. Examples of N-substituted fatty acid amides are fatty acid glucamides or fatty acid alkanolamides. Examples of esters are fatty acid esters, glycerol esters or monoglycerides. Examples of sugar-based surfactants are sorbitans, ethoxylated sorbitans, sucrose and glucose esters or alkylpolyglucosides. Examples of polymeric surfactants are home- or copolymers of vinylpyrrolidone, vinyl alcohols, or vinyl acetate.

Suitable cationic surfactants are quaternary surfactants, for example quaternary ammonium compounds with one or two hydrophobic groups, or salts of long-chain primary amines. Suitable amphoteric surfactants are alkylbetains and imidazolines. Suitable block polymers are block polymers of the A-B or A-B-A type comprising blocks of polyethylene oxide and polypropylene oxide, or of the A-B-C type comprising alkanol, polyethylene oxide and polypropylene oxide. Suitable polyelectrolytes are polyacids or polybases. Examples of polyacids are alkali salts of polyacrylic acid or polyacid comb polymers. Examples of polybases are polyvinylamines or polyethyleneamines.

Suitable adjuvants are compounds, which have a neglectable or even no pesticidal activity themselves, and which improve the biological performance of the compound I on the target. Examples are surfactants, mineral or vegetable oils, and other auxiliaries. Further examples are listed by Knowles, Adjuvants and additives, Agrow Reports DS256, T&F Informa UK, 2006, chapter 5.

Suitable thickeners are polysaccharides (e.g. xanthan gum, carboxymethylcellulose), inorganic clays (organically modified or unmodified), polycarboxylates, and silicates. Suitable bactericides are bronopol and isothiazolinone derivatives such as alkylisothiazolinones and benzisothiazolinones. Suitable anti-freezing agents are ethylene glycol, propylene glycol, urea and glycerin. Suitable anti-foaming agents are silicones, long chain alcohols, and salts of fatty acids. Suitable colorants (e.g. in red, blue, or green) are pigments of low water solubility and water-soluble dyes. Examples are inorganic colorants (e.g. iron oxide, titan oxide, iron hexacyanoferrate) and organic colorants (e.g. alizarin-, azo- and phthalocyanine colorants). Suitable tackifiers or binders are polyvinyl pyrrolidones, polyvinyl acetates, polyvinyl alcohols, polyacrylates, biological or synthetic waxes, and cellulose ethers.

The composition may be a composition for the use as cleaning composition, in particular if the particles contain a cleaning additive. In this case, preferably, the composition contains one or more of surfactants, bleaching agent, bleach catalysts, bleach activators, corrosion inhibitors, builders, enzymes, zinc salt.

Surfactants can be selected from anionic surfactants, amphoteric surfactants or non-inionic surfactants, preferably non-ionic surfactants. anionic surfactants are alkali metal and ammonium salts of C₈-C₁₈-alkyl sulfates, of C₈-C₁₈-fatty alcohol polyether sulfates, of sulfuric acid half-esters of ethoxylated C₄-C₁₂-alkylphenols (ethoxylation: 1 to 50 mol of ethylene oxide/mol), C₁₂-C₁₈ sulfo fatty acid alkyl esters, for example of C₁₂-C₁₈ sulfo fatty acid methyl esters, furthermore of C₁₂-C₁₈-alkylsulfonic acids and of C₁₀-C₁₈-alkylarylsulfonic acids, the sodium or potassium salts of stearic acid, oleic acid, palmitic acid, ether carboxylates, and alkylether phosphates. Amphoteric surfactants are those that bear a positive and a negative charge in the same molecule under use conditions. Preferred examples of amphoteric surfactants are so-called betaine-surfactants. Many examples of betaine-surfactants bear one quaternized nitrogen atom and one carboxylic acid group per molecule. A particularly preferred example of amphoteric surfactants is cocamidopropyl betaine (lauramidopropyl betaine). Non-ionic surfactants can be alkoxylated alcohols, di- and multiblock copolymers of ethylene oxide and propylene oxide and reaction products of sorbitan with ethylene oxide or propylene oxide, alkyl polyglycosides (APG), hydroxyalkyl mixed ethers and amine oxides.

Bleaching agents may be selected from chlorine bleach and peroxide bleach, and peroxide bleach may be selected from inorganic peroxide bleach and organic peroxide bleach. Preferred are inorganic peroxide bleaches, selected from alkali metal percarbonate, alkali metal perborate and alkali metal persulfate. Examples of organic bleaching agents are percarboxylic acids. The composition may contain 3 to 10 wt.-% of a bleaching agent.

Bleach catalysts can be selected from bleach-boosting transition metal salts or transition metal complexes such as, for example, manganese-, iron-, cobalt-, ruthenium- or molybdenum-salen complexes or carbonyl complexes. Manganese, iron, cobalt, ruthenium, molybdenum, titanium, vanadium and copper complexes with nitrogen-containing tripod ligands and also cobalt-, iron-, copper- and ruthenium-amine complexes can also be used as bleach catalysts.

Bleach activators may be selected from N-methylmorpholinium-acetonitrile salts (“MMA salts”), trimethylammonium acetonitrile salts, N-acylimides such as, for example, N-nonanoylsuccinimide, 1,5-diacetyl-2,2 dioxohexahydro-1,3,5-triazine (“DADHT”) or nitrile quats (trimethylammonium acetonitrile salts), tetraacetylethylenediamine (TAED) and tetraacetylhexylenediamine.

Corrosion inhibitors are typcially compounds which inhibit the corrosion of metal. Examples of suitable corrosion inhibitors are triazoles, in particular benzotriazoles, bisbenzotriazoles, aminotriazoles, alkylaminotriazoles, also phenol derivatives such as, for example, hydroquinone, pyrocatechol, hydroxyhydroquinone, gallic acid, phloroglucinol or pyrogallol. Preferably, the composition comprises 0.1 to 1.5 wt.-% corrosion inhibitor.

Builders may be selected from organic and inorganic builders. Examples of suitable inorganic builders are sodium sulfate or sodium carbonate or silicates, in particular sodium disilicate and sodium metasilicate, zeolites, sheet silicates, in particular those of the formula α-Na₂Si₂O₅, β-Na₂Si₂O₅, and δ-Na₂Si₂O₅, also fatty acid sulfonates, α-hydroxypropionic acid, alkali metal malonates, fatty acid sulfonates, alkyl and alkenyl disuccinates, tartaric acid diacetate, tartaric acid monoacetate, oxidized starch, and polymeric builders, for example polycarboxylates and polyaspartic acid. Examples of organic builders are especially polymers and copolymers. In one embodiment of the present invention, organic builders are selected from polycarboxylates, for example alkali metal salts of (meth)acrylic acid homopolymers or (meth)acrylic acid copolymers. Preferably, the composition contains 10 to 70 wt.-% builder.

Enzymes may be selected from lipases, hydrolases, amylases, proteases, cellulases, esterases, pectinases, lactases and peroxidases. Preferably, the composition contains 0.1 to 5 wt.-% enzyme.

Zinc salts can be selected from water-soluble and water-insoluble zinc salts. Water-insoluble is used to refer to those zinc salts which, in distilled water at 25° C., have a solubility of 0.1 g/l or less. Zinc salts which have a higher solubility in water are accordingly referred to within the context of the present invention as water-soluble zinc salts. Preferably, the zinc salt is selected from zinc benzoate, zinc gluconate, zinc lactate, zinc formate, ZnCl₂, ZnSO₄, zinc acetate, zinc citrate, Zn(NO₃)₂, Zn(CH₃SO₃)₂ and zinc gallate, preferably ZnCl₂, ZnSO₄, zinc acetate, zinc citrate, Zn(NO₃)₂, Zn(CH₃SO₃)₂ and zinc gallate, ZnO, ZnO·aq, Zn(OH)₂ and ZnCO₃.

### EXAMPLES

### Example 1 (Inventive)

Saflufenacil powder having a d50 of 2.4 μm was dried overnight in a vacuum oven at 80° C. A fluidized bed reactor having a volume of 300 ml, equipped with a vibration unit, was charged with 23 g of this dried saflufenacil powder. The powder was fluidized with N₂ gas (purity grade 5.0) under ambient pressure, heated to a temperature of 60° C. and exposed to trimethyl aluminum (TMA) vapor for 5 min. TMA was kept at 35° C. during the process. All precursor flow rates were at 100 sccm. After said time, the TMA vapor is removed by purging with nitrogen for 15 minutes. Subsequently, water vapor is brought in contact to the powder in the same manner as above for 5 min. After purging, 14 cycles consisting of 5 min TMA and 5 min water exposure are performed. Subsequently, the powder is split in half and 10 g are reintroduced into the reactor, which is heated to 100° C. 15 more cycles are performed with same dosing times as previously. A free-flowing white powder was obtained.

### Example 2 (Comparative)

Example 1 was repeated with the difference that the temperature at which the saflufenacil powder was exposed to TMA and water vapor was 100° C. for all cycles. Agglomeration and yellowing of the powder was observed.

1. A process for preparing coated organic particles comprising in the following order:
(a) bringing particles comprising an organic compound in motion to each other,
(b) sequentially contacting the organic particles with a metal- or semimetal-containing compound and a decomposition compound in the gaseous state at a first temperature, and
(c) sequentially contacting the organic particles with a metal- or semimetal-containing compound and a decomposition compound in the gaseous state at a second temperature, wherein the second temperature is at least 20° C. above the first temperature.

2. The process according to claim 1, wherein the first temperature is 40° C. to 90° C.

3. The process according to claim 1, wherein the second temperature is 60° C. to 150° C.

4. The process according to claim 1, wherein the organic particles are fluidized.

5. The process according to claim 1, wherein the metal- or semimetal-containing compound comprises Ti, Al, Si, Fe, Mg, Zn, Sn, Zr, or Hf.

6. The process according to claim 1, wherein in step (b) a sequence comprising contacting the organic particles with a metal- or semimetal-containing compound, removing residual metal- or semimetal-containing compound from the gas phase, contacting the organic particles with a decomposition compound and removing residual decomposition compound from the gas phase is performed 2 to 100 times.

7. The process according to claim 1, wherein in step (c) a sequence comprising contacting the organic particles with a metal- or semimetal-containing compound, removing residual metal- or semimetal-containing compound from the gas phase, contacting the organic particles with a decomposition compound and removing residual decomposition compound from the gas phase is performed 2 to 100 times.

8. The process according to claim 1, wherein the organic particles are brought in contact with a pretreatment compound in the gaseous state before step (b), wherein the pretreatment compound is water, an alcohol or a carboxylic acid.

9. The process according to claim 1, wherein the metal- or semimetal-containing compound in step (b) is different to the metal- or semimetal- containing compound in step (c) or the decomposition compound in step (b) is different to the decomposition compound in step (c).

10. An organic particles comprising a core and a shell, wherein
the core comprises an organic compound; and
the shell comprises an inner part and an outer part, wherein the inner part and the outer part comprise a metal or semimetal and wherein the inner part has a lower index of refraction than the outer part.

11. The organic particles according to claim 10, wherein the core has a weight-mean average particle size of 2 to 100 μm.

12. The organic particles according to claim 10, wherein shell has a thickness of 0.5 to 100 nm.

13. A composition containing the organic particles according to claim 10.

14. The composition according to claim 13, wherein the particles comprise an insecticide, fungicide, or herbicide and one or more auxiliaries selected from solvents, liquid carriers, solid carriers or fillers, surfactants, dispersants, emulsifiers, wetters, adjuvants, solubilizers, penetration enhancers, protective colloids, adhesion agents, thickeners, humectants, repellents, attractants, feeding stimulants, compatibilizers, bactericides, anti-freezing agents, anti-foaming agents, colorants, tackifiers and binders.

15. The composition according to claim 13, wherein the particles comprise a cleaning additive and one or more of surfactants, bleaching agent, bleach catalysts, bleach activators, corrosion inhibitors, builders, enzymes, and zinc salt.
